(19) United States
(12) Patent Application Publication
(10) Pub. No.: US 2017/0372998 A1
(43) Pub. Date: Dec. 28, 2017

(54) SHEET MOLDING PROCESS FOR WAFER LEVEL PACKAGING

(71) Applicant: Yenhao Benjamin Chen, Taipei City (TW)

(72) Inventor: Yenhao Benjamin Chen, Taipei City (TW)

(21) Appl. No.: 15/194,445

(22) Filed: Jun. 27, 2016

(51) Int. Cl. H01L 23/528; H01L 23/31; H01L 21/304; H01L 23/00; H01L 21/56

(52) U.S. Cl. CPC H01L 23/528; H01L 24/11; H01L 24/13; H01L 21/565; H01L 21/304; H01L 23/3171; H01L 24/06; H01L 2224/13022; H01L 2224/13021; H01L 2224/113; H01L 2224/11013; H01L 2224/10145; H01L 2224/05569; H01L 2224/0391; H01L 2224/0384; H01L 2224/03828; H01L 2224/03602; H01L 2224/036; H01L 2224/03436; H01L 2224/03013; H01L 2224/02215; H01L 2224/02206; H01L 2224/022; H01L 2224/0219; H01L 2224/02181; H01L 2224/02175; H01L 2224/13024; H01L 2224/81024; H01L 2224/023; H01L 2224/0401; H01L 2224/05124; H01L 2224/11849; H01L 2224/05147

(57) ABSTRACT

Discussed generally herein are methods and devices including or providing a redistribution layer device without under ball metallization. A device can include a substrate, electrical interconnect circuitry in the substrate, redistribution layer (RDL) circuitry electrically connected to the electrical interconnect circuitry, a conductive bump electrically connected to the RDL circuitry, the conductive bump interfacing directly with the RDL circuitry, and a sheet molding material over the substrate.

### TECHNICAL FIELD

This disclosure relates generally to wafer level die manufacturing and the resulting devices produced therefrom. One or more embodiments regard a manufacturing process to provide a device without an under bump metallization (UBM). In one or more embodiments, the process includes sheet molding on wafer level chip scale packaging (WLCSP).

### BACKGROUND ART

Chip manufacturing is often accomplished by creating a plurality of nearly identical dies on a single wafer. The routing for each die is repeated in discrete regions that are generally electrically isolated from one another. Each die is singulated from the wafer of dies. Dies that pass electrical testing can then be used in a device. There is often a prohibitive die loss in the manufacturing process.

### BRIEF DESCRIPTION OF THE DRAWINGS

FIGS. 1A-1I illustrate, by way of example, cross-section diagrams of an embodiment of a process for manufacturing a device with UBM.

FIG. 2A-2H illustrate, by way of example, cross section diagrams of another embodiment of a process for manufacturing a device without UBM.

FIG. 3A illustrates, by way of example, a cross-section diagram of an embodiment of a device manufactured using the process of FIGS. 1A-1L.

FIG. 3B illustrates, by way of example, a cross-section diagram of an embodiment of a device manufactured using the process of FIGS. 2A-2H.

FIG. 4 shows a block diagram example of an electronic device which can include a device with or without a UBM.

### DESCRIPTION OF EMBODIMENTS

The following description and the drawings sufficiently illustrate embodiments to enable those skilled in the art to practice them. Other embodiments can incorporate structural, logical, electrical, process, or other changes. Portions and features of some embodiments can be included in, or substituted for, those of other embodiments. Embodiments set forth in the claims encompass all available equivalents of those claims.

Embodiments discussed herein regard wafer level processes for creating devices and the resultant devices. One or more embodiments regard a manufacturing process to provide a device without under ball metallization (UBM). In one or more embodiments, the process includes sheet molding without UBM for wafer level chip scale packaging (WLCSP).

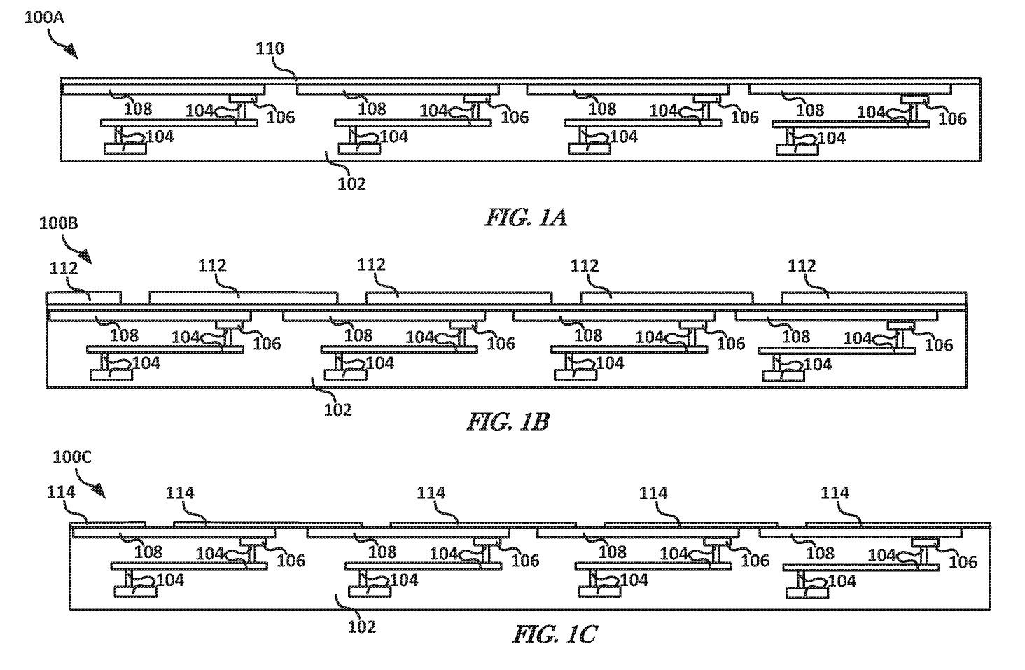

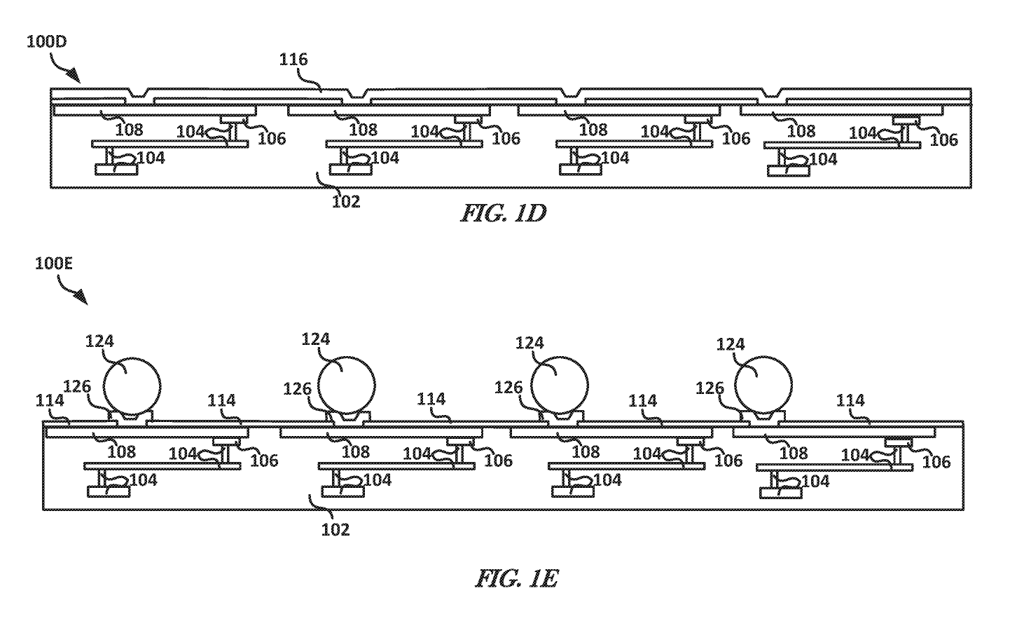

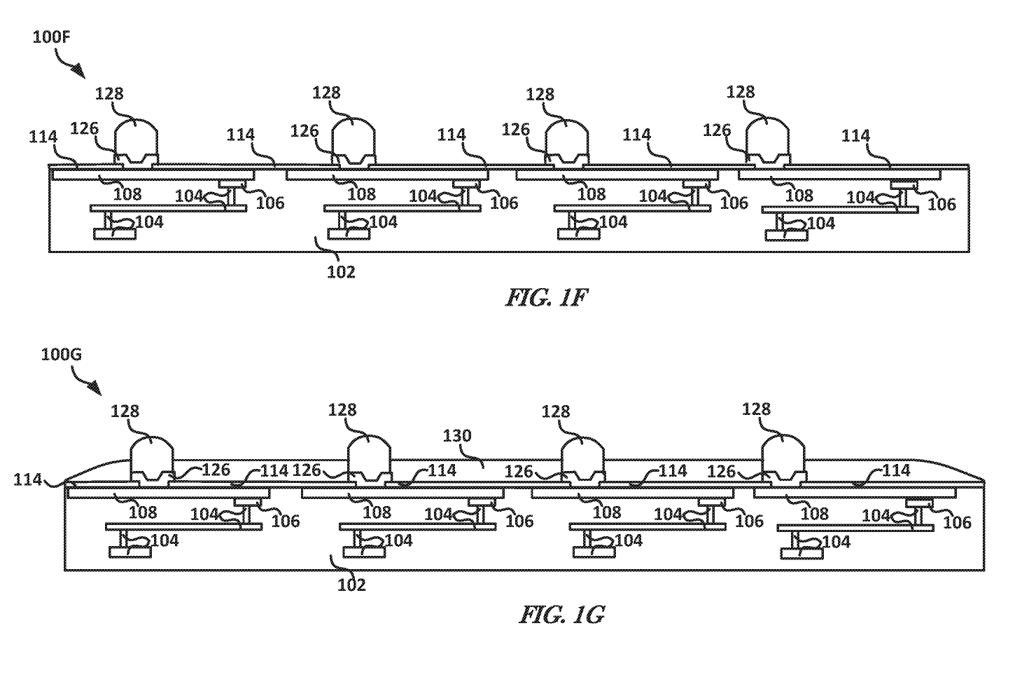

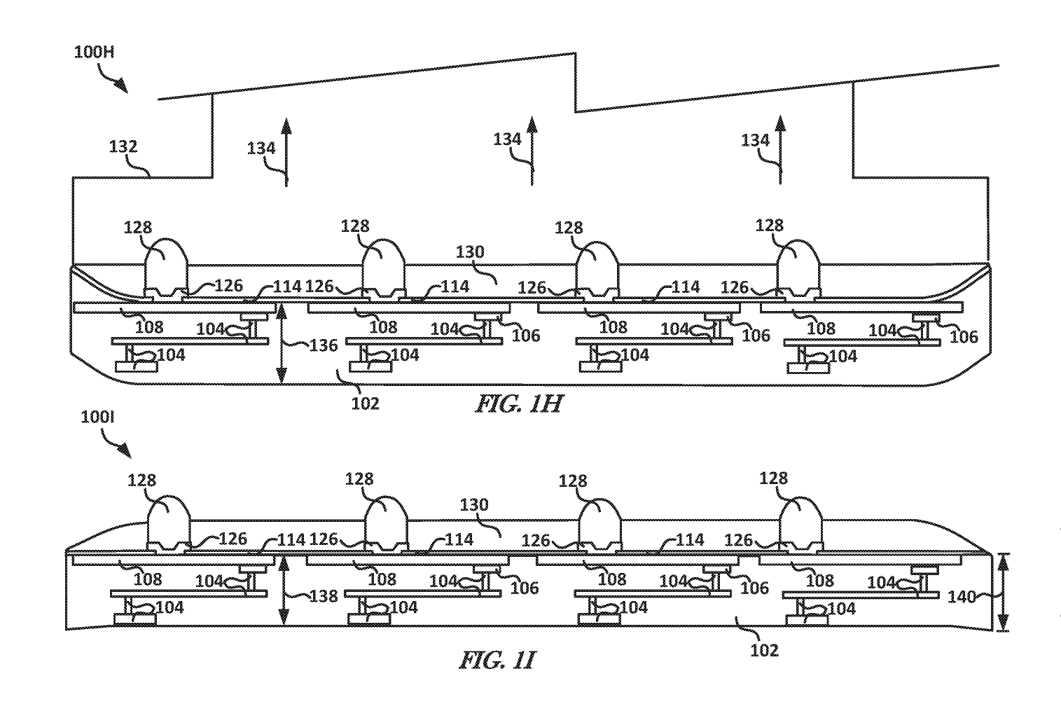

FIGS. 1A-1I illustrate, by way of example, cross-section diagrams that illustrate operations of a device manufacturing process illustrated at a wafer level. FIG. 1A illustrates, by way of example, an embodiment of a system 100A that includes a wafer 102 built up to include routing and electrical interconnect circuitry 104. A contact pad 106 is electrically connected to the metallization 104. A redistribution layer (RDL) 108 is electrically connected to the contact pad 106 to allow for electrical contact with the pad 106 and interconnect circuitry 104 at a different location than that of the pad 106. A passivation layer 110 is grown or otherwise situated on the RDL 108.

The wafer 102 is a slice of material (generally semiconductor material, such as crystalline silicon) used for the fabrication of integrated circuits (ICs). The wafer 102 provides a substrate on/in which the ICs are built. In building the ICs, the wafer 102 can be doped with ions, implanted with ions, etched, patterned (such as by photolithographic patterning or laser ablation, for example), or otherwise modified. Materials may be deposited, grown, or otherwise situated on or at least partially in the wafer 102 in the creation of the ICs. Crystalline silicon and Gallium arsenide are common wafer materials. The wafer 102 herein includes the interconnect circuitry 104, the pad 106, and the RDL 108. The wafer 102 can be fabricated using processes such as lithography, etching, deposition, oxidation, diffusion, or the like.

The interconnect circuitry 104 provides routing of signals, such as to provide an electrical signal to the IC or provide a signal from the IC. The interconnect circuitry 104 can include vias, contacts, and/or interconnects between one or more vias and one or more contacts. A contact is generally a metallic structure that includes a surface on which an electrical connection can be made. A via is generally a metallic-plated hole that provides an electrical signal from one layer of the wafer 102 to another layer of the wafer 102. An interconnect (sometimes referred to as a trace) is generally electrically connects a pad to a pad, a via to a via, or a pad to a via.

The RDL 108 includes conductive material that makes the signal of the pad 106 available in one or more locations other than the location of the pad 106. The RDL 108 can be used to make chip-to-chip bonding simpler. For example, a commercially available off the shelf (COTS) chip has bond pads (e.g., similar to the pad 106) that are placed for wire bonded surface mount, but an application may call for solder bumps and flip chip mounting. The RDL 108 can provide a solution that does not require re-designing the chip, but rather just requires the design and implementation of the RDL 108.

The passivation material 110 can be grown, or otherwise situated on the RDL 108. The passivation material 110 can include polyimide (PI), silicon nitride, silicon dioxide, titanium oxide, glass, and/or a combination thereof, among other polymers. The passivation material 110 is provided to make a material more resistant to effects of an external environment, such as air and water.

FIG. 1B illustrates, by way of example, a cross-section diagram of an embodiment of a system 100B that includes the system 100A after a resist material 112 is patterned on the passivation material 110. The resist material 112 can include poly(methyl methacrylate) (PMMA), poly(methyl glutarimide) (PMGI), phenol formaldehyde resin (e.g., diazonaphthoquinone (DNQ) and/or novolac), or other photo mask resistance materials. The resist material 112 generally protects material that is not exposed by the patterning of the resist material 112 (e.g., the material under the resist material 112, such as the passivation material 110). The resist material 112 can be situated on the passivation material 110, such as by sputtering or coating. The resist material 112 can be patterned, such as by photolithography.

FIG. 1C illustrates, by way of example, a cross-section diagram of an embodiment of a system 100C that includes the system 100B after some of the passivation material 110 has been removed to expose a portion of the RDL 108 and the resist material 112 has been removed. The passivation material 110 can be removed using an etching process, such as to form patterned passivation material 114. The resist material 112 can be removed using an etching process.

FIG. 1D illustrates, by way of example, a cross-section diagram of an embodiment of a system 100D that includes the system 100C after an under ball metallization (UBM) material 116 has been deposited or other situated on the patterned passivation material 114 and exposed portions of the RDL 108. The UBM material 116 is bonded to the RDL 108. The UBM material 116 generally hermetically seals the interconnect circuitry and prevents potential diffusion of metals into the wafer 102. In forming the UBM material 116, an oxidation layer is removed from the exposed RDL 108, such as by etching (e.g., sputter etching, ion etching, wet etching, or the like). The wafer 102 is generally exposed to chemicals to treat the exposed surface of the RDL 108. That treated surface is then plated (e.g., using an electroless process) with a conductive material that is solderable (e.g., tin, cadmium, gold, silver, palladium, rhodium, copper, bronze, brass, lead, nickel silver, beryllium copper, nickel, combinations thereof, or the like).

FIG. 1E illustrates, by way of example, a cross-section diagram of an embodiment of a system 100E that includes the system 100D after conductive balls 124 are situated on patterned UBM material 126. The UBM material 116 can be etched using a wet etch process. A patterned UBM material 126 is left after such etching. In one or more embodiments, only the UBM material that will form a contact pad for the conductive balls 124 remains after the etching.

FIG. 1F illustrates, by way of example, a cross-section diagram of an embodiment of a system 100F that includes the system 100E after the conductive balls 124 are reflowed onto the patterned UBM material 126. After the reflowing process, the conductive balls 124 make better contact with the patterned UBM material 126, such as by forming a more columnar shaped conductive bump 128.

FIG. 1G illustrates, by way of example, a cross-section diagram of an embodiment of a system 100G that includes the system 100F after a liquid mold 130 is deposited on exposed portions of the passivation material 114. The liquid mold 130 can be deposited and then solidified, such as by using a compression molding process. The liquid mold material 130 can include a liquid molding compound. The liquid mold material 130 can be deposited on exposed portions of the passivation material 114 and/or exposed portions of the patterned UBM material 126, or other material exposed when the liquid mold 130 is deposited.

Compression molding is process in which a molding material is placed, then pressure is applied to form the molding material into a desired shape. The pressure is maintained until the molding material is cured sufficiently enough to retain its shape. Molding materials used in a compression molding process are typically thermosetting resins, such as those discussed previously.

FIG. 1H illustrates, by way of example, a cross-section diagram of an embodiment of a system 100H that includes the system 100G after a vacuum device 132 has grabbed the system 100G. The vacuum device 132 is generally in contact with the system 100G near edges of the liquid mold 130. Due to the difficulty in getting the liquid mold 130 to be uniformly thick on the edges using a compression molding process, the system 100G is generally curved a little near the edges. The vacuum device 132 creates suction and pulls the system 100G in the direction of the arrows 134. This suction mechanically couples the system 100G to the vacuum device 132, holding the system 100G in place. The system is held in place for a wafer thinning process, sometimes referred to as a backside grind (BSG).

FIG. 1I illustrates, by way of example, a cross-section diagram of an embodiment of a system 100I that includes the system 100H after a BSG process has been used to thin the wafer 102. The wafer 102 before BSG has a first thickness indicated by the arrow 136 of FIG. 1I. After the BSG process, the wafer has thicknesses ranging from a second thickness indicated by arrow 138 and a third thickness indicated by arrow 140. Near the edges of the wafer 102 the thickness of the wafer can be non-uniform due, at least in part, to the non-uniform thickness of the liquid mold 130. The second thickness is less than the first thickness and less than or equal to the third thickness. The third thickness is less than or equal to the first thickness.

This bad planarity of the backside of the wafer (the side opposite the active side, where the active side is the one on which the conductive balls 124 are attached) results in die yield loss. Downstream processes, such as electrical testing of dies that are singulated from the wafer 102, can indicate that a die has a fault when it does not or a die may not have sufficient dimensions to fit in to a package it was manufactured for, among others. Another issue can include the liquid molding 130 causing insufficient vacuum pressure to hold the wafer in place. Such a result can cause the die manufacture process to terminate.

Discussed next is another process for manufacturing a die. This process is different from the process just discussed in that no UBM is present, a molding is provided that is more planar than the liquid molding, and fewer processing operations are performed, among other differences. The following process can provide increased yield through a more planar molding and less yield loss due to BSG or insufficient vacuum pressure.

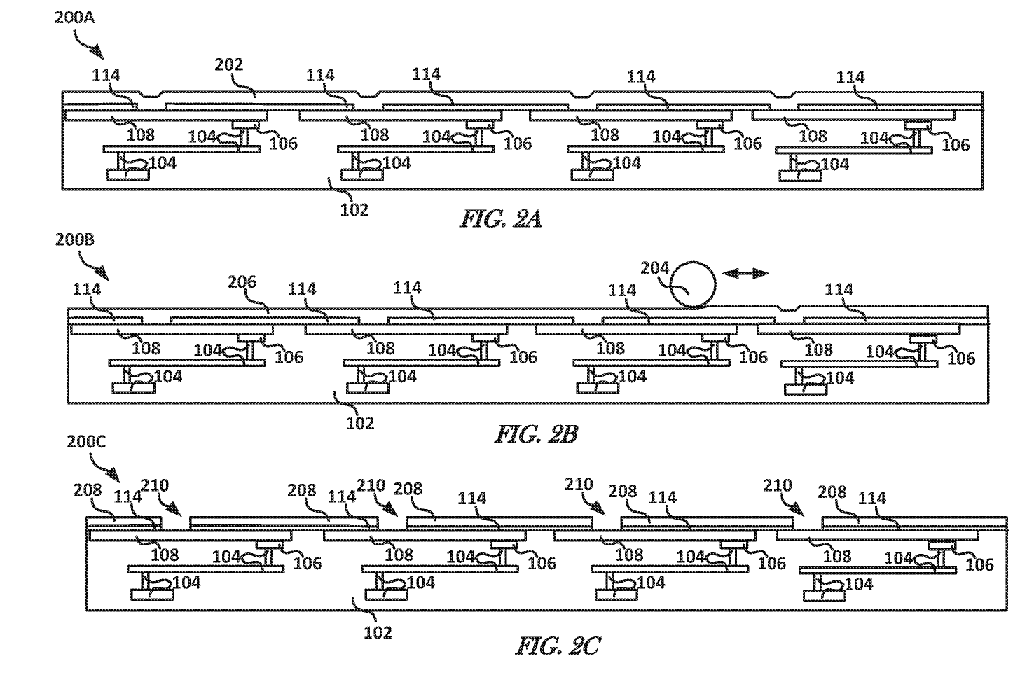

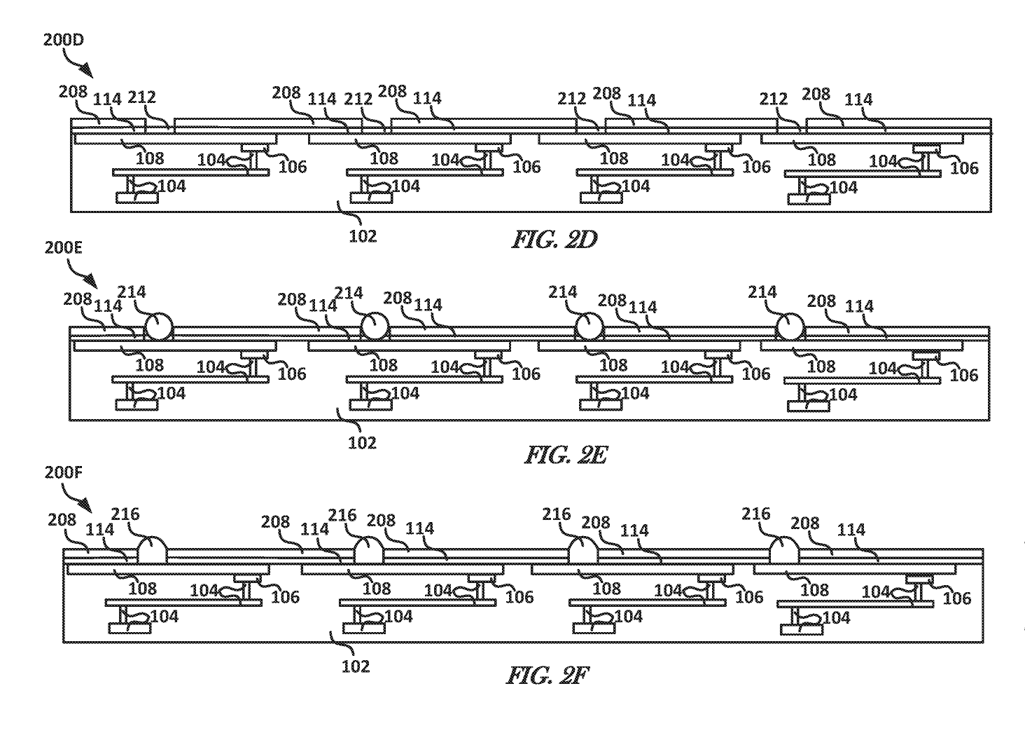

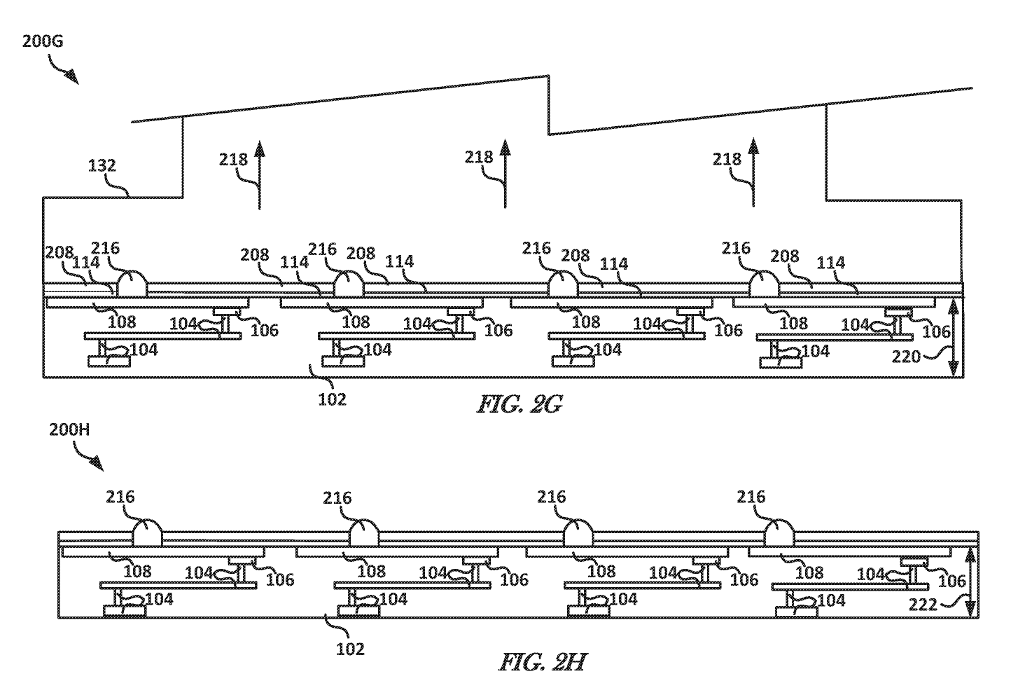

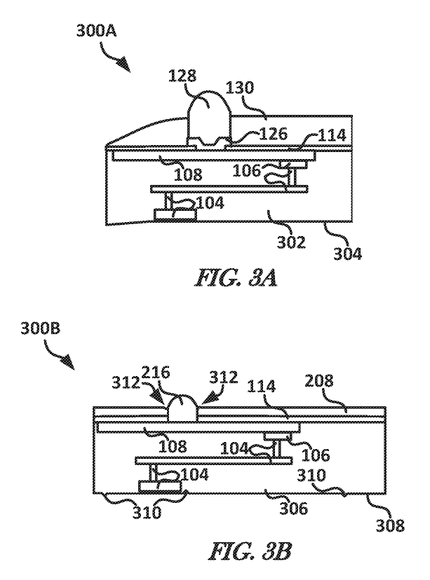

The combination of FIGS. 1A-1C and FIGS. 2A-2G illustrate, by way of example, cross-section diagrams that illustrate operations of a device manufacturing process illustrated at a wafer level. The process begins with the systems 100A, 100B, and 100C of FIGS. 1A-1C as previously described. FIG. 2A illustrates, by way of example, a cross-section diagram of an embodiment of a system 200A that includes the system 100C with a sheet molding 202 on the patterned passivation material 112 and exposed portions of the RDL 108. Since the patterned passivation material 112 is not planar, the sheet molding 202 on the patterned passivation material 112 is likewise generally non-planar. The sheet molding material 202 is a non-conductive, dielectric material. The sheet molding material 202 can include a tape-like epoxy molding (e.g., a back-side coating film). The sheet molding 202 can include a material used to provide a backside coating. Examples of such materials include a backside coating film from Lintec Corporation of Tokyo, Japan.

FIG. 2B illustrates, by way of example, a cross-section diagram of an embodiment of a system 200B that includes the system 200A after the sheet molding 202 is planarized, such as by rolling the sheet molding 202 with one or more rollers 204. The rollers can provide a specified amount of pressure over the surface of the sheet molding 202 to make the sheet molding material 202 more planar than it was prior to rolling. The sheet molding material 202 can be thinner, but more planar after rolling.

FIG. 2C illustrates, by way of example, a cross-section diagram of an embodiment of a system 200C that includes the system 200B after portions of the planarized molding material 206 are removed. Removing the planarized molding material can include laser ablating the planarized molding material 206. Laser ablating the planarized molding material 206 can form holes 210 through the planarized molding material 206, such as to expose a surface of the RDL circuitry 108. The holes 210 can be aligned with holes in the patterned passivation material 112, such as to expose the RDL circuitry 108. The RDL circuitry 108 can include copper, aluminum, other solderable conductive material, or a combination thereof.

A molding material that is laser ablated looks physically different from a molding material that is not laser ablated. A molding material that is laser ablated can include burn marks, such as can be visible to the naked eye or when viewed under a microscope, such as an electron microscope (e.g., a scanning electron microscope (SEM)). The lattice structure of a compression molded molding material is different and the chemical makeup of the compression molded molding material can be different from that of the sheet molding material as well. That is, different molding materials are suitable for different processes. These differences represent physical differences between a sheet molding material, a liquid deposited molding material, a compression molded molding material, and a laser ablated sheet molding material.

FIG. 2D illustrates, by way of example, a cross-section diagram of an embodiment of a system 200D that includes the system 200C after a flux 212 is situated on exposed portions of the RDL circuitry 108. The flux 212 is the same as the flux 122.

FIG. 2E illustrates, by way of example, a cross-section diagram of an embodiment of a system 200E that includes the system 200D after a conductive ball 214 is situated in the hole 210. An interface between the conductive ball 214 and the exposed RDL circuitry 108 can be cleaned by the flux 212, such as to help make a better connection between the conductive ball 214 and the RDL circuitry 108 after the conductive ball 214 is melted or reflowed.

FIG. 2F illustrates, by way of example, a cross-section diagram of an embodiment of a system 200F that includes the system 200E after the conductive ball 214 is reflowed to form the conductive bump 216. The reflow process can be performed at a temperature that is also sufficient for curing the patterned sheet molding material 208. If the reflow process is performed at a temperature insufficient for curing the patterned sheet molding material 208, the patterned sheet molding material 208 can be cured (if necessary or desired) in a separate operation.

FIG. 2G illustrates, by way of example, a cross-section diagram of an embodiment of a system 200G that includes the system 200F after the vacuum 132 has grabbed the system 200F. The vacuum 132 can secure the system 200F so that a backside of the wafer 102 (i.e. the side of the wafer opposite the active side, the active side includes the conductive bumps 216) can be accessed. The vacuum 132 can pull the system 200F in the direction of arrows 218, such as to secure the system 200F in place. A BSG process can be performed to reduce a thickness of the wafer 102. The thickness of the wafer 102 prior to the BSG process is indicated by the arrow 220.

FIG. 2H illustrates, by way of example, a cross-section diagram of an embodiment of a system 200H that includes the system 200G after the BSG process is performed. After the BSG process, the wafer 102 includes a thickness (indicated by the arrow 222) that is less than the thickness indicated by the arrow 220. The system 200H includes a wafer 102 with a backside that that is generally more planar than that of the system 100I. This increased planarity can help increase yield, especially on devices on the edge of the wafer 102. The increased planarity of the backside of the wafer is due, at least in part, to the sheet molding material used in the process of FIGS. 2A-2H being more planar than the liquid molding material used in the process of FIGS. 1A-1I.

FIG. 3A illustrates, by way of example, a cross-section diagram of an embodiment of a device 300A produced using the process of FIGS. 1A-1I. The device 300A illustrated is a device singulated from an edge of a wafer produced using the process of FIGS. 1A-1I. The device 300A as illustrated includes a substrate 302. The substrate 302 is a singulated portion of the wafer 102, singulated after processing the wafer 102 in a manner as shown in FIGS. 1A-1I. The substrate 302 includes interconnect circuitry 104 therein. RDL circuitry 108 is electrically connected to the interconnect circuitry 104 to provide access to the interconnect circuitry at a different location, such as through a pad of the interconnect circuitry 104.

The patterned passivation material 114 is situated on the substrate 302 and the RDL circuitry 108. The UBM 126 is electrically connected to the RDL circuitry 108. A conductive bump 128 is electrically connected to the interconnect circuitry 104 through the UBM 126 and the RDL circuitry 108. A compression molded molding material 130 is situated on the passivation material 114. The molding material 130 can be in contact with the UBM 126, such as at sides of the UBM 126. The molding material 130 can be in contact with the conductive bump 128, such as at sides of the conductive bump 128. The molding material 130 does not include burn marks from laser ablation as the molding material 130 is not laser ablated. The conductive bump 128 is not in direct contact with the RDL 108, as the conductive bump 128 is electrically connected to the RDL circuitry 108 through the UBM 126.

FIG. 3B illustrates, by way of example, a cross-section diagram of an embodiment of a device 300B produced using the process of FIGS. 2A-2H. The device 300B illustrated is a device singulated from an edge of a wafer produced using a process similar to that of FIGS. 1A-1C followed by FIGS. 2A-2H. The device 300B as illustrated includes a substrate 306. The substrate 306 is a singulated portion of the wafer 102, singulated after processing the wafer 102 in a manner as shown in FIGS. 2A-2H. The substrate 306 includes interconnect circuitry 104 therein. RDL circuitry 108 is electrically connected to the interconnect circuitry 104 to provide access to the interconnect circuitry 104 at a different location, such as through a pad of the interconnect circuitry 104.

The patterned passivation material 112 is situated on the substrate 306 and the RDL circuitry 108. A conductive bump 216 is electrically coupled to the interconnect circuitry 104 through the RDL circuitry 108. The conductive bump 216 is directly electrically and mechanically connected to the RDL circuitry 108. A planarized, laser ablated sheet molding material 208 is on the passivation material 112. The molding material 208 can be in contact with the conductive bump 216, such as at sides of the conductive bump 216. The molding material 208 includes burn marks from laser ablation as the molding material 216 is laser ablated to form a hole in which the conductive bump 216 is connected to the RDL circuitry 108. The molding material 208 is generally more planar than the molding material 130. A planarized sheet molding material is generally more planar than a compression molded material.

A backside 304 of the die 300A is generally less planar than a backside 306 of the die 300B. This is due, at least in part to the strength of the connection between the vacuum 132 and the wafer 102 and the warpage of the wafer 102 realized when the molding material 130 is not sufficiently planar. The molding material 130 is generally less planar than the molding material 208, so the warpage in the device 300A is generally greater than that in the device 300B. Such increased warpage reduces package yield and increases costs in manufacturing. By making the molding material more planar, such increases in yield loss can be avoided. The molding material can be made more planar using a sheet molding process, such as that shown in FIGS. 2A-2H and/or planarizing the molding material, such as shown in FIG. 2B.

Laser ablating the molding material 208 can leave burn marks or other detectable physical features 312, such as a bump or pit in the planarized molding material 208. The physical features 312 are generally located at sidewalls of the holes 210 (i.e. the locations of the molding material 208 which were laser ablated. Grinding the backside 308 can leave a grind mark, such as a bump or pit (physical feature 310) on the backside 308.

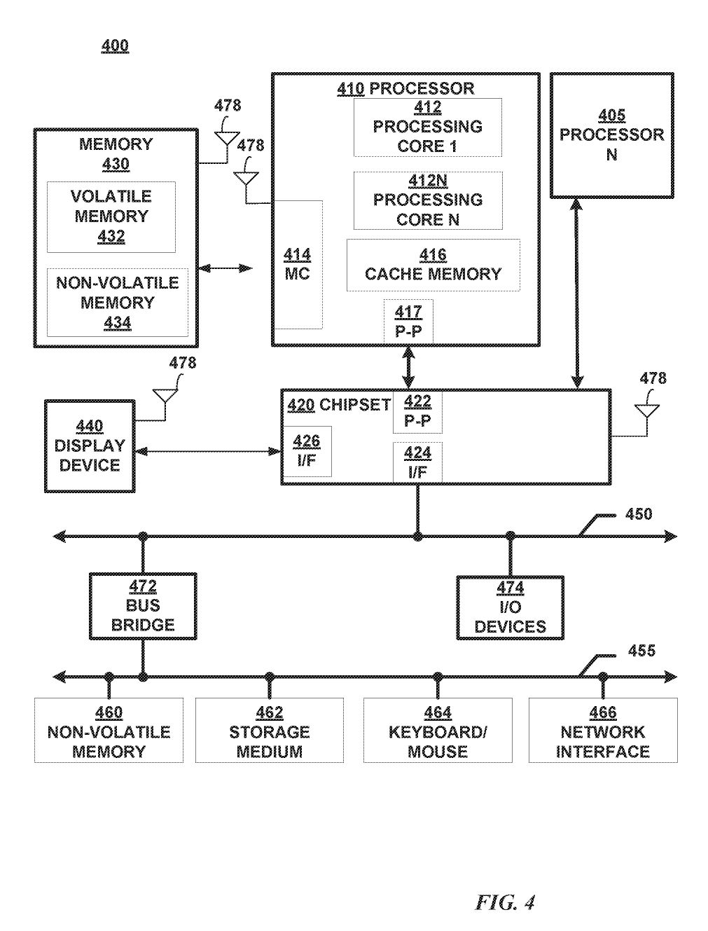

FIG. 4 illustrates, by way of example, a logical block diagram of an embodiment of a system 400 that includes components which can include a package fabricated in a manner discussed herein. The packages discussed herein can include one or more of the items of the system 400.

In one embodiment, processor 410 has one or more processing cores 412 and 412N, where 412N represents the Nth processor core inside processor 410 where N is a positive integer. In one embodiment, system 400 includes multiple processors including 410 and 405, where processor 405 has logic similar or identical to the logic of processor 410. In some embodiments, processing core 412 includes, but is not limited to, pre-fetch logic to fetch instructions, decode logic to decode the instructions, execution logic to execute instructions and the like. In some embodiments, processor 410 has a cache memory 416 to cache instructions and/or data for system 400. Cache memory 416 may be organized into a hierarchal structure including one or more levels of cache memory.

In some embodiments, processor 410 includes a memory controller 414, which is operable to perform functions that enable the processor 410 to access and communicate with memory 430 that includes a volatile memory 432 and/or a non-volatile memory 434. In some embodiments, processor 410 is coupled with memory 430 and chipset 420. Processor 410 may also be coupled to a wireless antenna 478 to communicate with any device configured to transmit and/or receive wireless signals. In one embodiment, the wireless antenna interface 478 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 432 includes, but is not limited to, Synchronous Dynamic Random Access Memory (SDRAM), Dynamic Random Access Memory (DRAM), RAIVIBUS Dynamic Random Access Memory (RDRAM), and/or any other type of random access memory device. Non-volatile memory 434 includes, but is not limited to, flash memory, phase change memory (PCM), read-only memory (ROM), electrically erasable programmable read-only memory (EEPROM), or any other type of non-volatile memory device.

Memory 430 stores information and instructions to be executed by processor 410. In one embodiment, memory 430 may also store temporary variables or other intermediate information while processor 410 is executing instructions. In the illustrated embodiment, chipset 420 connects with processor 410 via Point-to-Point (PtP or P-P) interfaces 417 and 422. Chipset 420 enables processor 410 to connect to other elements in system 400. In some embodiments of the invention, interfaces 417 and 422 operate in accordance with a PtP communication protocol such as the Intel® QuickPath Interconnect (QPI) or the like. In other embodiments, a different interconnect may be used.

In some embodiments, chipset 420 is operable to communicate with processor 410, 405N, display device 440, and other devices. Chipset 420 may also be coupled to a wireless antenna 478 to communicate with any device configured to transmit and/or receive wireless signals.

Chipset 420 connects to display device 440 via interface 426. Display 440 may be, for example, a liquid crystal display (LCD), a plasma display, cathode ray tube (CRT) display, or any other form of visual display device. In some embodiments of the invention, processor 410 and chipset 420 are merged into a single SOC. In addition, chipset 420 connects to one or more buses 450 and 455 that interconnect various elements 474, 460, 462, 464, and 466. Buses 450 and 455 may be interconnected together via a bus bridge 472. In one embodiment, chipset 420 couples with a non-volatile memory 460, a mass storage device(s) 462, a keyboard/mouse 464, and a network interface 466 via interface 424 and/or 404, etc.

In one embodiment, mass storage device 462 includes, but is not limited to, a solid state drive, a hard disk drive, a universal serial bus flash memory drive, or any other form of computer data storage medium. In one embodiment, network interface 466 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the components shown in FIG. 4 are depicted as separate blocks within the system 400, the functions performed by some of these blocks may be integrated within a single semiconductor circuit or may be implemented using two or more separate integrated circuits. For example, although cache memory 416 is depicted as a separate block within processor 410, cache memory 416 (or selected aspects of 416) can be incorporated into processor core 412.

### ADDITIONAL NOTES AND EXAMPLES

In Example 1 a device includes a substrate, electrical interconnect circuitry in the substrate, redistribution layer (RDL) circuitry electrically connected to the electrical interconnect circuitry, a conductive bump electrically connected to the RDL circuitry, the conductive bump forming a direct interface with the RDL circuitry, and a sheet molding material over the substrate.

In Example 2 the device of Example 1 can include patterned passivation material on portions of the RDL circuitry and portions of the substrate between the sheet molding material and the substrate.

In Example 3 the device of at least one of Examples 1-2 can include, wherein the molding material is a sheet molding material.

In Example 4 the device of Example 3 can include, wherein the molding material is a planarized sheet molding material.

In Example 5 the device of at least one of Examples 1-4 can include, wherein the molding material includes first holes therethrough, the passivation material includes second holes therethrough, the first holes and the second holes are at least partially aligned, and the conductive bump is situated in the aligned first and second holes.

In Example 6 the device of Example 5 can include, wherein the first holes are laser ablated leaving burn marks on the molding material.

In Example 7 the device of at least one of Examples 1-6 can include, wherein the RDL circuitry includes one or more pads formed thereon that includes copper or aluminum.

In Example 8 the device of at least one of Examples 1-7 can include, wherein the interconnect circuitry includes a contact pad electrically connected to a via and wherein the RDL circuitry includes conductive material patterned to provide electrical access to the contact pad at a location different from a location of the contact pad.

In Example 9 the device of at least one of Examples 1-8 can include, wherein the patterned passivation material includes a polyimide or silicon dioxide.

In Example 10 the device of at least one of Examples 1-9 can include, wherein the wafer is thinned leaving grind marks on a backside of the wafer.

In Example 11 a wafer includes a plurality of devices, each device of the plurality of devices comprising electrical interconnect circuitry in the wafer, redistribution layer (RDL) circuitry electrically connected to the electrical interconnect circuitry, a conductive bump electrically connected to the RDL circuitry, the conductive bump directly on the RDL circuitry, and a molding material over the substrate, the molding material including burn marks from a laser ablation process used to form first holes in the molding material.

In Example 12 the wafer of Example 11 can include, wherein each device of the plurality of devices further comprises patterned passivation material on portions of the RDL circuitry and portions of the substrate between the molding material and the substrate.

In Example 13 the wafer of at least one of Examples 11-12 can include, wherein the molding material is a rolled sheet molding material.

In Example 14 the wafer of at least one of Examples 12-13 can include, wherein the molding material includes first holes therethrough, the passivation material includes second holes therethrough, the first holes and the second holes are at least partially aligned, and the conductive bump is situated in the aligned first and second holes.

In Example 15 the wafer of Example 14 can include, wherein the first holes are laser ablated leaving burn marks on the molding material.

In Example 16 the wafer of at least one of Examples 11-15 can include, wherein the RDL circuitry includes one or more pads formed thereon that includes copper or aluminum.

In Example 17 the wafer of at least one of Examples 11-16 can include, wherein the interconnect circuitry includes a contact pad electrically connected to a via and wherein the RDL circuitry includes conductive material patterned to provide electrical access to the contact pad at a location different from a location of the contact pad.

In Example 18 the wafer of at least one of Examples 12-17 can include, wherein the patterned passivation material includes a polyimide or silicon dioxide.

In Example 19 the wafer of at least one of Examples 11-18 can include, wherein the wafer is thinned leaving grind marks on a backside of the wafer.

In Example 20 a method includes situating a molding material on a wafer, laser ablating first holes in the molding material to expose portions of redistribution layer (RDL) circuitry of the wafer, the RDL circuitry electrically connected to a contact pad of interconnect circuitry in the wafer, reflowing a conductive ball to from a conductive bump in electrical and mechanical contact with the RDL circuitry, and grinding a backside of the wafer to thin the wafer, the backside of the wafer opposite an active side of the wafer, the active side of the wafer is the side on which the conductive bump is located.

In Example 21 the method of Example 20 can include planarizing the molding material prior to laser ablating the first holes in the molding material.

In Example 22 the method of at least one of Examples 20-21 can include, wherein the molding material is a sheet of molding material covering substantially all of a surface area of an active surface of the wafer.

In Example 23 the method of at least one of Examples 21-22 can include, wherein planarizing the molding material includes rolling the molding material to increase a planarity of the molding material.

In Example 24 the method of at least one of Examples 20-23 can include, grabbing, after reflowing the conductive ball and with a vacuum, an active side of the wafer, and wherein grinding a backside of the wafer includes grinding the backside of the wafer while the wafer is grabbed by the vacuum.

In Example 25 the method of at least one of Examples 20-24 can include, situating a passivation material on exposed portions of the RDL circuitry and on exposed portions of the wafer, and patterning the passivation material to expose portions of the RDL circuitry to create patterned passivation material with second holes therethrough, wherein the first holes and the second holes are at least partially aligned, and the conductive bump is situated in the aligned first and second holes.

The above description of embodiments includes references to the accompanying drawings, which form a part of the description of embodiments. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) can be used in combination with each other. Other embodiments can be used such as by one of ordinary skill in the art upon reviewing the above description. The Abstract is provided to allow the reader to quickly ascertain the nature of the technical disclosure. It is submitted with the understanding that it will not be used to interpret or limit the scope or meaning of the claims. Also, in the above description of embodiments, various features can be grouped together to streamline the disclosure. This should not be interpreted as intending that an unclaimed disclosed feature is essential to any claim. Rather, inventive subject matter can lie in less than all features of a particular disclosed embodiment. Thus, the following claims are hereby incorporated into the description of embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1. A device comprising:
a substrate;
electrical interconnect circuitry in the substrate;
redistribution layer (RDL) circuitry electrically connected to the electrical interconnect circuitry;
a conductive bump electrically connected to the RDL circuitry, the conductive bump forming a direct interface with the RDL circuitry through a flux; and
a molding material over the substrate wherein the molding material is a backside coating film.

2. The device of claim 1, further comprising:
patterned passivation material on portions of the RDL circuitry and portions of the substrate between the molding material and the substrate.

3. The device of claim 2, wherein the molding material is a planarized molding material.

4. The device of claim 3, wherein the molding material includes first holes therethrough, the passivation material includes second holes therethrough, the first holes and the second holes are at least partially aligned, and the conductive bump is situated in the aligned first and second holes, in direct contact with the RDL circuitry, and does not include an under bump metallization (UBM).

5. The device of claim 4, wherein the first holes are laser ablated leaving burn marks on the molding material on an exposed surface of the molding material and abutting the conductive bump.

6. The device of claim 1, wherein the RDL circuitry includes one or more pads formed thereon, the one or more pads including copper or aluminum,

7. The device of claim 6, wherein the electrical interconnect circuitry includes a contact pad electrically connected to a via and wherein the RDL circuitry includes conductive material patterned to provide electrical access to the contact pad at a location different from a location of the contact pad.

8. The device of claim 2, wherein the patterned passivation material includes a polyimide or silicon dioxide.

9. The device of claim 1, wherein the substrate is thinned leaving grind marks on a backside of the substrate.

10. A wafer comprising a plurality of devices, each device of the plurality of devices comprising:
electrical interconnect circuitry in the wafer;
redistribution layer (RDL) circuitry electrically connected to the electrical interconnect circuitry;
a conductive bump electrically connected to the RDL circuitry, the conductive bump forming a direct interface with the RDL circuitry through a flux material; and
a molding material over the substrate, the sheet molding material including burn marks on an exposed surface thereof, wherein the molding material is a backside coating film.

11. The wafer of claim 10, wherein each device of the plurality of devices further comprises:
patterned passivation material on portions of the RDL circuitry and portions of the substrate between the molding material and the wafer.

12. The wafer of claim 11, wherein the molding material is a rolled molding material.

13. The wafer of claim 12, wherein the molding material includes first holes therethrough, the passivation material includes second holes therethrough, the first holes and the second holes are at least partially aligned, and the conductive bump is situated in the at least partially aligned first and second holes, in direct contact with the RDL, circuitry, and does not include an under bump metallization (UBM).

14. The wafer of claim 11, further comprising one or more pads formed on the RDL circuitry, the one or more pads including copper or aluminum.

15-20. (canceled)
